(19) United States
(12) Patent Application Publication
(10) Pub. No.: US 2019/0172932 A1
(43) Pub. Date: Jun. 6, 2019

(54) MANUFACTURING METHOD OF THIN FILM TRANSISTOR, THIN FILM TRANSISTOR AND DISPLAY SUBSTRATE

(71) Applicants: HEFEI XINSHENG OPTOELECTRONICS TECHNOLOGY CO., LTD., Anhui (CN); BOE TECHNOLOGY GROUP CO., LTD., Beijing (CN)

(72) Inventors: Haijiao QIAN, Beijing (CN); Binbin CAO, Beijing (CN); Chengshao YANG, Beijing (CN); Yinhu HUANG, Beijing (CN)

(73) Assignees: HEFEI XINSHENG OPTOELECTRONICS TECHNOLOGY CO., LTD., Anhui (CN); BOE TECHNOLOGY GROUP CO., LTD., Beijing (CN)

(21) Appl. No.: 16/322,272

(22) PCT Filed: Feb. 1, 2018
(86) PCT No.: PCT/CN2018/074924

§ 371 Date: Jan. 31, 2019

(30) Foreign Application Priority Data
Jun. 2, 2017 (CN) 201710409082.9

(51) Int. Cl. H01L 29/66; H01L 29/786; H01L 21/311; H01L 21/308

(52) U.S. Cl. CPC H01L 29/66765; H01L 29/78675; H01L 29/78666; H01L 21/308; H01L 29/78669; H01L 29/66757; H01L 21/31144; H01L 29/78678

(57) ABSTRACT

The present disclosure provides a manufacturing method of thin film transistor, a thin film transistor and a display substrate. The manufacturing method comprises sequentially forming a polysilicon pattern layer and a protective pattern layer on a substrate; etching the protective pattern layer with a first etching gas, so as to obtain a protective pattern; simultaneously etching the protective pattern and the polysilicon pattern layer with a second etching gas by using the protective pattern as a mask, so as to obtain a polysilicon pattern and a residual protective pattern, the protective pattern being etched with the second etching gas at a rate no less than that for etching the polysilicon pattern layer; and forming an amorphous silicon pattern, which is in contact with etched sides of the polysilicon pattern, exposes a part of the residual protective pattern, and forms an active layer together with the polysilicon pattern.

### CROSS-REFERENCE TO RELATED APPLICATION

The present application claims the priority of Chinese Patent Application No. 201710409082.9 filed on Jun. 2, 2017, the contents of which are incorporated herein in their entirety by reference.

### TECHNICAL FIELD

The present disclosure relates to display field, and particularly relates to a manufacturing method of thin film transistor, a thin film transistor and a display substrate.

### BACKGROUND

With the development of liquid crystal display technology, a requirement to electron mobility of an active layer of a thin film transistor is increasing, while an active layer purely made of amorphous silicon materials can no longer satisfy the performance requirements in terms of electron mobility (low electron mobility of a semiconductor layer may lead to low on-state current of the thin film transistor). Current solution to the above problem is to use a double-layer structure of polysilicon and amorphous silicon as an active layer, because electron mobility of a polysilicon layer is high enough in on state to compensate for insufficient electron mobility of an amorphous silicon layer. However, in related art, due to bad contact between an amorphous silicon pattern and a polysilicon pattern in the active layer of the thin film transistor, the electron mobility of the thin film transistor is lowered.

### SUMMARY

In one aspect, embodiments of the present disclosure provide a manufacturing method of thin film transistor, comprising steps of forming an active layer, which include:

forming a polysilicon pattern layer and a protective pattern layer on a substrate sequentially;

etching the protective pattern layer with a first etching gas, so as to obtain a protective pattern formed from the protective pattern layer;

simultaneously etching the protective pattern and the polysilicon pattern layer with a second etching gas by using the protective pattern as a mask, so as to obtain a polysilicon pattern formed from the polysilicon pattern layer and a residual protective pattern formed from the protective pattern, wherein the protective pattern is etched with the second etching gas at a rate no less than a rate at which the polysilicon pattern layer is etched with the second etching gas; and

forming an amorphous silicon pattern, which is in contact with etched sides of the polysilicon pattern, and forms an active layer together with the polysilicon pattern;

In some embodiments, materials for forming the polysilicon pattern layer include p-Si, and materials for forming the protective pattern layer include SiO₂.

In some embodiments, the step of etching the protective pattern layer with a first etching gas comprises:

etching the protective pattern layer with the first etching gas composed of O₂ and CF₄ in a volume ratio of 40:200.

In some embodiments, the protective pattern layer has a thickness of about 1000 Å, a period of etching the protective pattern layer with the first etching gas is in a range of 120s to 130s, and an atmospheric pressure of etching environment is in a range of 55 mTorr to 65 mTorr.

In some embodiments, the step of simultaneously etching the protective pattern and the polysilicon pattern layer with a second etching gas comprises:

simultaneously etching the protective pattern and the polysilicon pattern layer with the second etching gas composed of O₂ and CF₄ in a volume ratio of 100:200.

In some embodiments, the polysilicon pattern layer has a thickness of about 500 Å, a period of simultaneously etching the protective pattern and the polysilicon pattern layer with the second etching gas is in a range of 35s to 45s, and an atmospheric pressure of etching environment is in a range of 75 mTorr to 85 mTorr.

In some embodiments, the manufacturing method further comprises:

after the amorphous silicon pattern is formed, performing ion implantation to a surface of the amorphous silicon pattern away from the substrate, so as to form an ohmic contact layer by an ion implanted part of the amorphous silicon pattern.

In another aspect, the embodiments of the present disclosure further provide a thin film transistor, which is manufactured with the above manufacturing method provided according to the present disclosure.

In some embodiments, the thin film transistor comprises an active layer; wherein the active layer comprises a polysilicon pattern, a residual protective pattern and an amorphous silicon pattern. In some embodiments, the polysilicon pattern has a first surface, a second surface and etched sides, the first surface and the second surface are opposite surfaces of the polysilicon pattern, and the etched sides are located between the first and second surfaces; and an area of the first surface is smaller than that of the second surface. The residual protective pattern is provided on the first surface. The amorphous silicon pattern is in contact with the etched sides and a part of the first surface, and exposes a part of the residual protective pattern.

In some embodiments, the amorphous silicon pattern is in contact with the entire etched sides.

In some embodiments, a projection area of the residual protective pattern on the first surface is smaller than the area of the first surface.

In some embodiments, the etched sides are obliquely located between the first and second surfaces.

In some embodiments, the first surface is an upper surface of the polysilicon pattern; the second surface is a lower surface of the polysilicon pattern; and the etched sides extend upwards from the second surface and towards an inside direction of the polysilicon pattern to the first surface.

In some embodiments, an angle between the etched side and the second surface is in a range of 45 degrees to 55 degrees.

In some embodiments, the etched side has a slope ranging from 45 degrees to 55 degrees.

In some embodiments, the polysilicon pattern and the residual protective pattern form an ascending step structure.

Furthermore, the embodiments of the present disclosure further provide a display substrate, comprising the above thin film transistor provided according to the present disclosure.

### BRIEF DESCRIPTION OF THE DRAWINGS

FIG. 1 is a schematic structural diagram of a thin film transistor in related art;

FIGS. 2A to 2D are schematic flow charts of a manufacturing method of thin film transistor provided according to embodiments of the present disclosure;

FIGS. 3A to 3G are detailed flow charts of the manufacturing method of thin film transistor provided according to embodiments of the present disclosure;

FIG. 4 is a schematic view showing comparison between a thin film transistor provided according to embodiments of the present disclosure and a thin film transistor of related art in terms of an on-state current;

FIG. 5 is a schematic structural diagram of a thin film transistor provided according to embodiments of the present disclosure.

### DETAILED DESCRIPTION OF THE EMBODIMENTS

In order to make the objects, the technical solutions and the advantages of the present disclosure more apparent, the present disclosure will be described hereinafter in a clear and complete manner in conjunction with the drawings and embodiments.

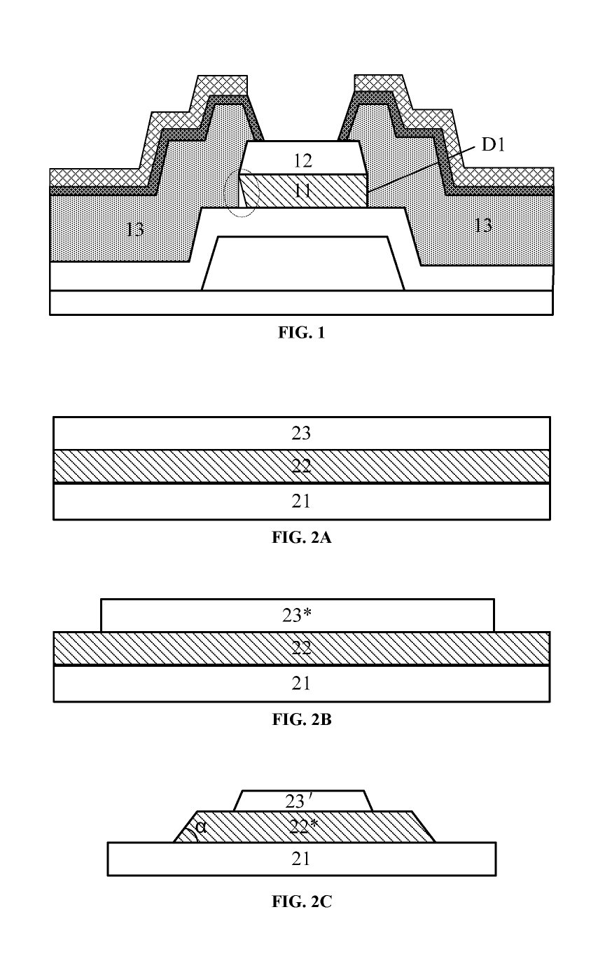

As shown in FIG. 1, in a manufacturing method of thin film transistor in related art, a protective pattern 12 is deposited on a polysilicon layer, and is then used as a mask to etch the polysilicon layer, so as to obtain a polysilicon pattern 11 as shown in FIG. 1, and then an amorphous silicon pattern 13 is formed to be in contact with an etched side D1 of the polysilicon pattern 11.

During the process of etching the polysilicon layer, the protective pattern 12 is hardly etched with an etching gas, therefore, under the masking effect of the protective pattern, the etched side D1 of the polysilicon pattern 11 is made nearly perpendicular to a contact surface with the protective pattern 12, and even an over etching phenomena as shown by an elliptical dotted line in FIG. 1 may happen (i.e., a part of the polysilicon pattern 11 is concave relative to the protective pattern thereabove). Obviously, contact between the polysilicon layer and the amorphous silicon pattern 13 may be affected by the etched side of the polysilicon layer such that a contact area therebetween is limited, which may affect electron mobility of the thin film transistor and further deteriorate working performance of the thin film transistor.

The present disclosure provides a solution to the problem in related art that the electron mobility of the thin film transistor is lowered due to bad contact between the amorphous silicon pattern and the polysilicon pattern in the active layer of the thin film transistor.

In one aspect, embodiments of the present disclosure provide a manufacturing method of thin film transistor, comprising steps of forming an active layer, wherein the steps include S1-S4.

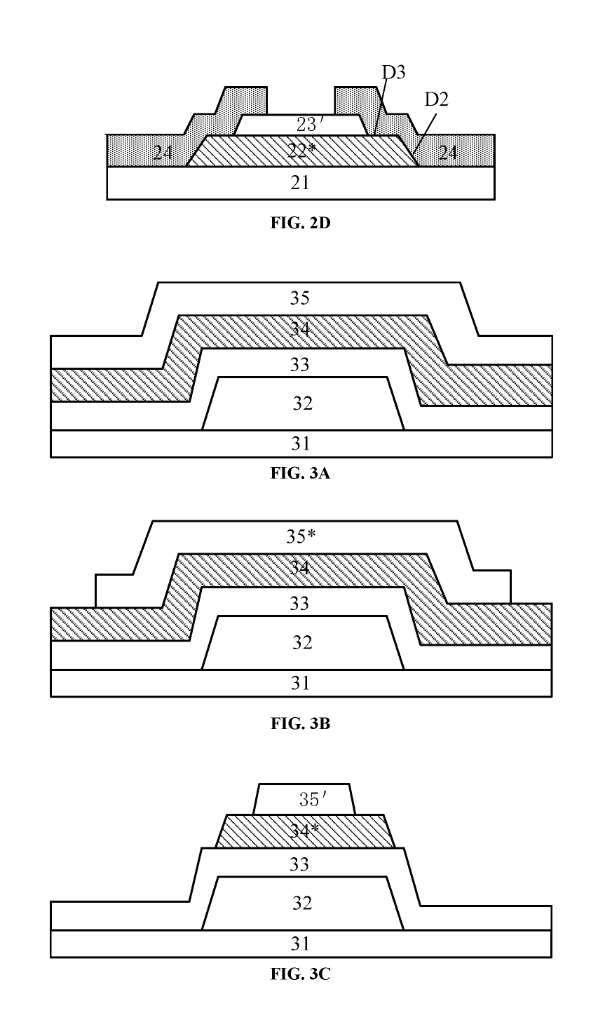

In step S1, with reference to FIG. 2A, forming a polysilicon pattern layer 22 and a protective pattern layer 23 sequentially on a substrate 21.

In step S2, with reference to FIG. 2B, etching the protective pattern layer 23 with a first etching gas, so as to obtain a protective pattern 23* formed from the protective pattern layer 23.

In step S3, with reference to FIG. 2C, simultaneously etching the protective pattern 23* and the polysilicon pattern layer 22 with a second etching gas by using the protective pattern 23* as a mask, so as to obtain a polysilicon pattern 22* formed from the polysilicon pattern layer 22 and a residual protective pattern 23′ formed from the protective pattern 23*.

In Step S3, the protective pattern 23* is etched with the second etching gas at a rate no less than (i.e., higher than or equal to) a rate at which the polysilicon pattern layer 22 is etched with the second etching gas. Therefore, during the whole etching process, a part of the polysilicon pattern layer 22 is always exposed on two sides of the protective pattern 23*, so that etched sides D2 of the polysilicon pattern layer 22 may be formed at a certain slope a.

In step S4, with reference to FIG. 2D, forming an amorphous silicon pattern 24 on the substrate 21, the amorphous silicon pattern 24 being in contact with the etched sides of the polysilicon pattern 22* and exposing a part of the residual protective pattern 23′, wherein the polysilicon pattern 22* and the amorphous silicon pattern 24 together form an active layer of the thin film transistor.

By comparing FIG. 1 with FIG. 2D, it can be seen that the manufacturing method of the embodiments may produce the polysilicon pattern 22* having sloped etched sides, and it is obvious that a contact area between the etched side D2 having the gentle slope and the amorphous silicon pattern 24 is larger than that between the etched side D1 with the amorphous silicon pattern 13 shown in FIG. 1. Therefore, the thin film transistor produced with the manufacturing method according to the present embodiment has higher electron mobility, and thus is capable of achieving better working performance.

Moreover, when the etching process is completed, a deposition area of the residual protective pattern 23′ is smaller than that of the polysilicon pattern 22*, so that the polysilicon pattern 22* and the residual protective pattern 23′ may form an ascending step structure. With the step structure, the amorphous silicon pattern 24 extends from the etched sides D2 to above the residual protective pattern 23′ by stacking, so as to be brought into contact with an upper surface D3 of a part of the polysilicon pattern 22* beyond the residual protective pattern 23′, which further increases a contact area between the polysilicon pattern 22* and the amorphous silicon pattern 24. Moreover, the step structure may facilitate climbing of the amorphous silicon pattern 24 and reduce probability of fracture of the amorphous silicon pattern 24.

In conjunction with practical application, the manufacturing method of the embodiments will be described in detail below.

Taking a manufacturing method for producing bottom-gate thin film transistor as example, the method of the present embodiment includes the following steps S31-S37.

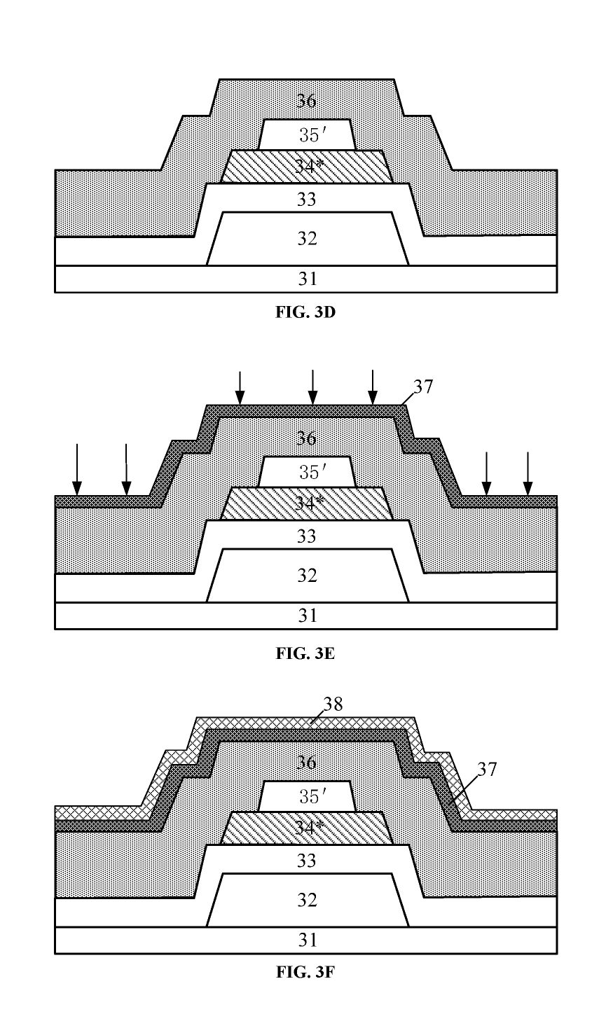

In step S31, as shown in FIG. 3A, a gate electrode 32, a gate insulation layer 33, a polysilicon pattern layer 34 and a protective pattern layer 35 are sequentially disposed on a substrate 31.

Specifically, for forming the gate electrode 32 in Step S31, sputtering or thermal evaporation may be used to deposit a gate metal layer on the substrate on which Step S31 is performed, the gate metal layer may be made of Cu, Al, Ag, Mo, Cr, Nd, Ni, Mn, Ti, Ta, W or an alloy thereof, and may be a single-layer structure, or a multi-layer structure such as Cu\Mo, Ti\Cu\Ti, and Mo\Al\Mo. The gate metal layer is coated with a layer of photoresist, and the photoresist is exposed with a mask to form a photoresist removing region and a photoresist retaining region, wherein the photoresist retaining region corresponds to a pattern region of the gate electrode 32, and the photoresist removing region corresponds to a region other than the pattern of the gate electrode 32; a development process is performed to completely remove the photoresist from the photoresist removing region, while a thickness of the photoresist in the photoresist retaining region remains unchanged; and an etching process is performed to completely remove a gate metal film from the photoresist removing region and strip away the residual photoresist, so as to form the gate electrode 32.

Specifically, for forming the gate insulation layer 33 in Step S31, the gate insulation layer 33 can be deposited on the substrate 31 on which the gate electrode 32 is formed by using a plasma enhanced chemical vapor deposition (PECVD) method, the gate insulation layer 33 may be made of oxides, nitrides or oxygen and nitrogen compounds, and corresponding reaction gases may be SiH4, NH3, N2 or SiH₂C1₂, NH₃, N₂.

Specifically, in Step S31, the polysilicon pattern layer 34 is made of p-Si, and has a thickness of about 500 Å, and the protective pattern layer 35 is made of SiO₂, and has a thickness of about 1000 Å; and the polysilicon pattern layer 34 may be formed by depositing a layer of a-Si on the gate insulation layer 33, irradiating the a-Si layer with high energy density laser by means of Micro Lens Array (MLA) process in related art to make a-Si to melt, then crystallize, and finally be converted to p-Si, so as to obtain the polysilicon pattern layer 34. It should be noted that the word “about” in the present disclosure indicates an error range of less than 2%, 5%, 8% or 10%.

In step S32, the protective pattern layer 35 shown in FIG. 3A is etched with a first etching gas composed of o₂ and CF₄ in a volume ratio of 40:200, so as to obtain a protective pattern 35* shown in FIG. 3B which is configured to serve as a mask for subsequent etching of the polysilicon pattern layer 34.

It has been found that, with the first etching gas in the above volume ratio, it is the protective pattern layer 35 that is to be mainly etched while the polysilicon pattern layer 34 is hardly etched in the etching process; wherein the protective pattern layer 35 has a thickness of about 1000 Å, then a duration of etching the protective pattern layer 35 with the first etching gas is in a range of 120s to 130s (about 125s). An atmospheric pressure of the etching environment is in a range of 55 mTorr to 65 mTorr (about 60 mTorr).

In step S33, by using the protective pattern 35* shown in FIG. 3B as a mask, the protective pattern 35* and the polysilicon pattern layer 34 are simultaneously etched with a second etching gas which is composed of O₂ and CF₄ in a volume ratio of 100:200, so as to obtain a polysilicon pattern 34* formed from the polysilicon pattern layer 34, and a residual protective pattern 35′ formed from the protective pattern 35*as shown in FIG. 3C.

It has been found that, with the second etching gas in the above volume ratio, the protective pattern layer 35 and the polysilicon pattern layer 34 are mainly etched in the etching process; wherein the polysilicon pattern layer 34 has a thickness of 500 Å, then a duration of etching the protective pattern layer 35 and the polysilicon pattern layer 34 with the second etching gas is in a range of about 35s to 45s (about 40s). And an atmospheric pressure of the etching environment is in a range of 75 mTorr 85 mTorr (about 80 mTorr).

In step S34, as shown in FIG. 3D, a-Si is deposited so as to form an amorphous silicon pattern layer 36.

In step S35, as shown in FIG. 3E, ion implantation is performed to a surface of the amorphous silicon pattern layer 36 away from the substrate 31 so as to form an ohmic contact layer 37 by a ion implanted part of the amorphous silicon pattern layer 36.

It should be noted that the ohmic contact layer 37 formed in Step S35 is provided to improve working performance of the thin film transistor, but Step S35 is not a necessary step of the embodiments.

In step S36, as shown in FIG. 3F, a metal layer 38 is deposited.

Specifically, magnetron sputtering, thermal evaporation or other filming methods may be used to deposit the metal layer 38 in Step S36, and the metal layer 38 may be made of Cu, Al, Ag, Mo, Cr, Nd, Ni, Mn, Ti, Ta, W or an alloy thereof. Moreover, the metal layer 38 may be a single-layer structure, or a multi-layer structure such as Cu\Mo, Ti\Cu\Ti, and Mo\Al\Mo.

In step S37, as shown in FIG. 3G, the metal layer 38, the ohmic contact layer 37 and the amorphous silicon pattern layer 36 are simultaneously etched by use of a mask, so as to obtain a source electrode 381 and a drain electrode 382 formed from the metal layer 38, and an amorphous silicon pattern 36* formed from the amorphous silicon pattern 36, wherein the source electrode 381, the drain electrode 382 and the amorphous silicon pattern 36* expose a part of the residual protective pattern 35′; and the amorphous silicon pattern 36* includes two parts which are separated from each other at a position where the part of the residual protective pattern 35′ is exposed.

Specifically, in Step S37, the metal layer 38 may be coated with a layer of photoresist, and the photoresist is exposed with a mask to form a photoresist removing region and a photoresist retaining region, wherein the photoresist retaining region corresponds to a pattern region of the source electrode 381 and the drain electrode 382, and the photoresist removing region corresponds to a region other than the pattern region of the source electrode 381 and the drain electrode 382; a development process is performed to completely remove the photoresist from the photoresist removing region, while a thickness of the photoresist in the photoresist retaining region remains unchanged; and an etching process is performed to completely remove parts of the metal layer 38, the ohmic contact layer 37 and the amorphous silicon pattern layer 36 which are positioned in the photoresist removing region, and strip away the residual photoresist, so as to form the source electrode 381, the drain electrode 382 and the amorphous silicon pattern 36*.

Obviously, the manufacturing method of the present embodiments provides an improvement to an etching process of active layer, thereby a contact area between the amorphous silicon pattern 36* and the polysilicon pattern 34* can be effectively increased. The manufacturing method is easily to be implemented in practical application, and has high practical value.

It should be noted that the above practical application is only exemplary for describing the technical solution of the embodiments, but makes no limitation to the protection scope of the present disclosure. It should be understood by those of ordinary skill in the art that the technical solution of the embodiments may also be configured to form the amorphous silicon pattern 36* before depositing the metal layer 38, and then performing ion implantation to a surface of the amorphous silicon pattern 36* away from the substrate 31 to form the ohmic contact layer 37. Moreover, the technical solution of the embodiments may also be applied to manufacturing of a top-gate thin film transistor, which will not be described herein because the manufacturing principle is the same.

Based on the above, another embodiment of the present disclosure provides a thin film transistor accordingly, wherein an active layer of the thin film transistor is obtained by the manufacturing method provided by the present disclosure.

As shown in FIG. 3G, according to the manufacturing method of the present application, the etched side of the polysilicon pattern 34* of the thin film transistor of the embodiment may have a slope a ranging from 45 degrees to 55 degrees, and the polysilicon pattern 34* and the residual protective pattern 35′ form an ascending step structure, such that the contact area between the amorphous silicon pattern 36* and the polysilicon pattern 34* can be increased.

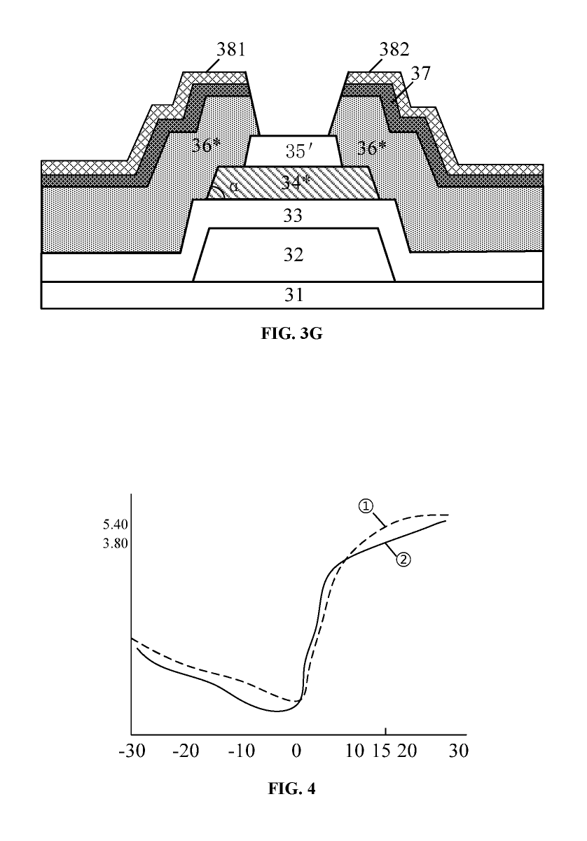

In practical application, with reference to FIG. 4 which is a diagram showing a comparison between an on-state current of the thin film transistor provided according to the embodiment of the present disclosure and an on-state current of the thin film transistor of related art, where the dotted line represents the thin film transistor of the embodiment, the solid line represents the thin film transistor of related art, the horizontal coordinate represents an on-state voltage in Volts, and the vertical coordinate represents an on-state current in mA.

In general, an on-state voltage of a thin film transistor in a display substrate is set to be 15V.

With reference to \textcircled{2} in FIG. 4, as for a thin film transistor of the related art, when its on-state voltage is 15V, its on-state current is about 3.8 mA and corresponding electron mobility is about 4.05; with reference to \textcircled{1} in FIG. 4, as for a thin film transistor of the present disclosure, when its on-state voltage is 15V, its on-state current is about 5.4 mA and corresponding electron mobility is about 7.10.

Obviously, the thin film transistor of the present embodiment has greater on-state current and higher electron mobility, and thus has better working performance than that of the thin film transistor of the related art.

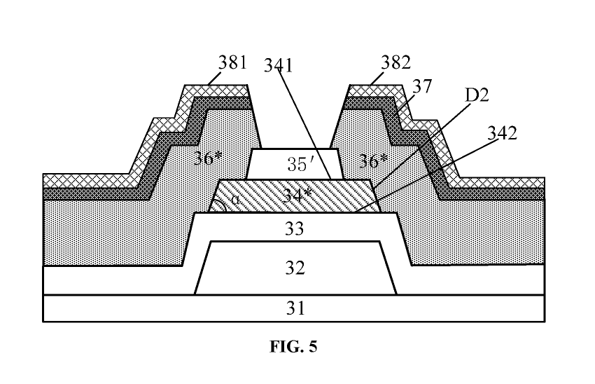

In one embodiment, as shown in FIG. 5, the thin film transistor comprises an active layer, wherein the active layer comprises the polysilicon pattern 34*, the residual protective pattern 35′ and the amorphous silicon pattern 36*. The polysilicon pattern 34* has a first surface 341, a second surface 342 and etched sides D2, the first surface 341 and the second surface 342 are two opposite surfaces of the polysilicon pattern 34*, and the etched sides D2 are located between the first surface 341 and the second surface 342; and an area of the first surface 341 is smaller than that of the second surface 342. The residual protective pattern 35′ is provided on the first surface 341, and a projection area of the residual protective pattern 35′ on the first surface 341 is smaller than the area of the first surface 341. The amorphous silicon pattern 36* is in contact with the etched sides D2 and a part of the first surface 341, and exposes a part of the residual protective pattern 35′.

When the thin film transistor is in a situation as shown in FIG. 5, the first surface 341 is an upper surface of the polysilicon pattern 34*; the second surface 342 is a lower surface of the polysilicon pattern 34*; and the etched sides D2 extend upwards from the second surface 342 and towards an inside direction of the polysilicon pattern 34* to the first surface 341. The etched sides D2 and the second surface 342 form an angle of 45 degrees to 55 degrees.

Accordingly, the embodiments of the present disclosure further provide a display substrate comprising the aforesaid thin film transistor. With the thin film transistor, the display substrate of the embodiments may drive image display in a more stable way, so as to guarantee user experience and has high practical value.

In each method embodiment of the present disclosure, sequence numbers of the steps are not used to limit an order of the steps. The order of the steps can be changed by those of ordinary skill in the art without any creative work, and the changed steps also fall into the protection scope of the present disclosure

Unless otherwise defined, any technical or scientific terms used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than being limited to physical or mechanical connection. Such words as “on/above”, “under/below”, “left” and “right” are merely used to represent relative position relationship, and when an absolute position of an object is changed, the relative position relationship will be changed too.

It should be appreciated that when an element such as a layer, a film, a region or a substrate is described to be “above” or “below” another element, the element may be “directly” “on” or “below” the other element, or has intermediate elements therebetween.

The above are optional embodiments of the present disclosure. It should be noted that those of ordinary skill in the art may make various improvements and modifications without departing from the principle of the present disclosure, and these improvements and modifications also fall into the protection scope of the present disclosure.

1. A manufacturing method of thin film transistor, comprising steps of forming an active layer, which comprise:
forming a polysilicon pattern layer and a protective pattern layer on a substrate sequentially;
etching the protective pattern layer with a first etching gas, so as to obtain a protective pattern formed from the protective pattern layer;
simultaneously etching the protective pattern and the polysilicon pattern layer with a second etching gas by using the protective pattern as a mask, so as to obtain a polysilicon pattern formed from the polysilicon pattern layer and a residual protective pattern formed from the protective pattern, wherein the protective pattern is etched with the second etching gas at a rate no less than a rate at which the polysilicon pattern layer is etched with the second etching gas; and
forming an amorphous silicon pattern, which is in contact with etched sides of the polysilicon pattern, exposes a part of the residual protective pattern, and forms an active layer together with the polysilicon pattern.

2. The manufacturing method of claim 1, wherein, materials for forming the polysilicon pattern layer comprise p-Si, and materials for forming the protective pattern layer comprise SiO₂.

3. The manufacturing method of claim 2, wherein,
the step of etching the protective pattern layer with a first etching gas comprises:
etching the protective pattern layer with the first etching gas composed of O₂ and CF₄ in a volume ratio of 40:200.

4. The manufacturing method of claim 3, wherein,
the protective pattern layer has a thickness of about 1000 Å, a period of etching the protective pattern layer with the first etching gas is in a range of 120s to 130s, and an atmospheric pressure of etching environment is in a range of 55 mTorr to 65 mTorr.

5. The manufacturing method of claim 2, wherein,
the step of simultaneously etching the protective pattern and the polysilicon pattern layer with a second etching gas comprises:
simultaneously etching the protective pattern and the polysilicon pattern layer with the second etching gas composed of O₂ and CF₄ in a volume ratio of 100:200.

6. The manufacturing method of claim 5, wherein,
the polysilicon pattern layer has a thickness of about 500 Å, a period of simultaneously etching the protective pattern and the polysilicon pattern layer with the second etching gas is in a range of 35s to 45s, and an atmospheric pressure of etching environment is in a range of 75 mTorr to 85 mTorr.

7. The manufacturing method of claim 1, further comprising:
after the amorphous silicon pattern is formed, performing ion implantation to a surface of the amorphous silicon pattern away from the substrate, so as to form an ohmic contact layer by an ion implanted part of the amorphous silicon pattern.

8. A thin film transistor, comprising an active layer; wherein the active layer comprises:
a polysilicon pattern which has a first surface, a second surface and etched sides, the first surface and the second surface are opposite surfaces of the polysilicon pattern, and the etched sides are located between the first and second surfaces; and an area of the first surface is smaller than that of the second surface;
a residual protective pattern on the first surface; and
an amorphous silicon pattern which is in contact with the etched sides and a part of the first surface, and exposes a part of the residual protective pattern.

9. The thin film transistor of claim 8, wherein the amorphous silicon pattern is in contact with the entire etched sides.

10. The thin film transistor of claim 8, wherein a projection area of the residual protective pattern on the first surface is smaller than the area of the first surface.

11. The thin film transistor of claim 8, wherein the etched sides are obliquely located between the first surface and the second surface.

12. The thin film transistor of claim 8, wherein the first surface is an upper surface of the polysilicon pattern; the second surface is a lower surface of the polysilicon pattern; and the etched sides extend upwards from the second surface and towards an inside direction of the polysilicon pattern to the first surface.

13. The thin film transistor of claim 12, wherein an angle between the etched side and the second surface is in a range of 45 degrees to 55 degrees.

14. The thin film transistor of claim 8, wherein the etched side has a slope ranging from 45 degrees to 55 degrees.

15. The thin film transistor of claim 8, wherein the polysilicon pattern and the residual protective pattern form an ascending step structure.

16. A display substrate, comprising the thin film transistor of claim 8.
